(19) United States
(12) Patent Application Publication
(10) Pub. No.: US 2025/0326063 A1
(43) Pub. Date: Oct. 23, 2025

(54) CONDUCTIVE ASSEMBLY, ENERGIZING APPARATUS, LASER-INDUCED METALLIZATION DEVICE AND PRODUCTION LINE

(71) Applicant: LAPLACE (WUXI) SEMICONDUCTOR TECHNOLOGY CO., LTD., Wuxi (CN)

(72) Inventors: Feng SUN, Wuxi (CN); Qi KONG, Wuxi (CN); Xuedi DONG, Wuxi (CN)

(73) Assignee: LAPLACE (WUXI) SEMICONDUCTOR TECHNOLOGY CO., LTD., Wuxi (CN)

(21) Appl. No.: 18/759,424

(22) Filed: Jun. 28, 2024

(30) Foreign Application Priority Data
Apr. 18, 2024 (CN) 202410476255.9

(51) Int. Cl. B23K 26/354; B23K 37/04; H01L 31/18

(52) U.S. Cl. CPC B23K 26/354; B23K 37/0408; H10F 71/1375

(57) ABSTRACT

Disclosed are a conductive assembly, an energizing apparatus, a laser-induced metallization device and a production line, solving a problem that if mounting accuracy of a pressing needle is not high or the pressing needle undergoes positional deviation during a pressing process, it is easy for the pressing needle to fail to contact a grid line, resulting in the pressing needle failing to conduct electricity. The conductive assembly includes a first mounting component and a plurality of pressing needles. The plurality of pressing needles are separately connected to the first mounting component. The pressing needle includes a contact portion, and the plurality of contact portions are arranged in a first direction and arranged in at least two rows in a direction perpendicular to the first direction.

### CROSS-REFERENCE TO RELATED APPLICATIONS

The present disclosure claims priority to Chinese Patent Application No. 202410476255.9, filed on Apr. 18, 2024, which is incorporated herein by reference in its entirety.

### TECHNICAL FIELD

The present disclosure relates to the field of semiconductor or photovoltaic technologies, and in particular, to a conductive assembly, an energizing apparatus, a laser-induced metallization device and a production line.

### BACKGROUND

Contact resistance between a surface electrode and a rear surface electrode of a photovoltaic cell has a significant impact on conversion efficiency of a cell. The lower a metal-semiconductor contact resistance, the higher a conversion efficiency. At present, a main way to reduce the metal-semiconductor contact resistance is a laser enhanced contact optimization (LECO) process, also known as a laser-assisted sintering process or a laser-induced metallization process. High-intensity laser irradiation is used to excite charge carriers in the photovoltaic cell, and a deflection voltage is applied to the photovoltaic cell to separate carriers, forming a local current and triggering sintering to reduce a contact resistance between a metal and a semiconductor.

In related technologies, when LECO process is performed on the photovoltaic cell, a laser source scans grid lines on a surface of the photovoltaic cell one by one, a pressing needle is required to accurately contact the grid lines on the surface of the photovoltaic cell. Therefore, high mounting accuracy is required for the pressing needle, and the pressing needle may undergo positional deviation during a pressing process. If the mounting accuracy of the pressing needle is not high or the pressing needle undergoes positional deviation during the pressing process, the pressing needle is easy to fail to contact the grid line, resulting in the pressing needle failing to conduct electricity.

### SUMMARY

An embodiment of the present disclosure provides a conductive assembly, applied to a laser-induced metallization device for processing a sheet-like material. The conductive assembly and the sheet-like material are capable of moving towards or away from each other, and the conductive assembly is capable of electrical connecting to a grid line of a first surface of the sheet-like material. The conductive assembly includes: a first mounting component; and a plurality of pressing needles, separately connected to the first mounting component. Each of the plurality of pressing needles includes a contact portion, a plurality of contact portions are arranged in a first direction and arranged in at least two rows in a direction perpendicular to the first direction, and for two adjacent rows of contact portions, at least one of the contact portions in a first row extends between adjacent contact portions in a second row. In a case that at least one of the plurality of contact portions is in contact with the grid line, the first direction is the same as an extension direction of the grid line.

### BRIEF DESCRIPTION OF THE DRAWINGS

FIG. 1 is a schematic structural diagram of a laser-induced metallization device according to an embodiment of the present disclosure.

FIG. 2 is a schematic structural diagram of an energizing apparatus and a driving assembly according to an embodiment of the present disclosure.

FIG. 3 is a schematic structural diagram of a conductive assembly according to an embodiment of the present disclosure.

FIG. 4 is a front view of a conductive assembly according to an embodiment of the present disclosure.

FIG. 5a is a schematic structural diagram of a contact portion of a pressing needle and a grid line according to an embodiment of the present disclosure.

FIG. 5b is a schematic structural diagram of a contact portion of a pressing needle and a grid line according to another embodiment of the present disclosure.

FIG. 5c is a schematic structural diagram of a contact portion of a pressing needle and a grid line according to another embodiment of the present disclosure.

FIG. 5d is a schematic structural diagram of a contact portion of a pressing needle and a grid line according to another embodiment of the present disclosure.

FIG. 5e is a schematic structural diagram of a contact portion of a pressing needle and a grid line according to another embodiment of the present disclosure.

FIG. 6 is a side view of an energizing apparatus and a driving assembly according to an embodiment of the present disclosure.

FIG. 7 is a schematic structural diagram of a laser-induced metallization production line according to an embodiment of the present disclosure.

FIG. 8 is a schematic structural diagram of a laser-induced metallization production line according to another embodiment of the present disclosure.

FIG. 9 is a partially enlarged view of an area M of the laser-induced metallization production line shown in FIG. 8.

### DETAILED DESCRIPTION OF THE EMBODIMENTS

The technical schemes in the embodiments of the present disclosure will be described clearly and completely below in combination with the accompanying drawings in the embodiments of the present disclosure. Obviously, the described embodiments are only a part of the embodiments of the present disclosure, not all of the embodiments. Based on the embodiments in the present disclosure, all other embodiments obtained by those skilled in the art without creative efforts shall fall within the protection scope of the present disclosure.

Contact resistance between a surface electrode and a rear surface electrode of a photovoltaic cell has a significant impact on a filling factor and conversion efficiency. The lower a metal-semiconductor contact resistance, the higher the filling factor and conversion efficiency. Therefore, a technology of converting a cell sheet with poor performance due to excessive contact resistance into a cell sheet with normal performance by reducing the metal-semiconductor contact resistance has become an urgent need for major battery manufacturers.

At present, a main way to reduce the metal-semiconductor contact resistance is a LECO process, also known as a laser assisted sintering process or a laser-induced metallization process. High-intensity laser irradiation is used to excite charge carriers in the photovoltaic cell, and a deflection voltage is applied to the photovoltaic cell to separate carriers, forming a local current and triggering sintering to reduce a contact resistance between a metal and a semiconductor, thereby improving the conversion efficiency of the photovoltaic cell.

In related technologies, when LECO process is performed on the photovoltaic cell, a laser source scans grid lines on a surface of the photovoltaic cell one by one, a pressing needle is required to accurately contact the grid lines on the surface of the photovoltaic cell. Therefore, high mounting accuracy is required for the pressing needle, and the pressing needle may undergo positional deviation during a pressing process. If the mounting accuracy of the pressing needle is not high or the pressing needle undergoes positional deviation during the pressing process, the pressing needle is easy to fail to contact the grid line, resulting in the pressing needle failing to conduct electricity.

With regard to the above-mentioned problem, an embodiment of the present disclosure provides a conductive assembly, applied to a laser-induced metallization device for processing a sheet-like material. The conductive assembly and the sheet-like material are capable of moving towards or away from each other, and the conductive assembly is capable of electrical connecting to a grid line of a first surface of the sheet-like material. The conductive assembly includes: a first mounting component and a plurality of pressing needles. The plurality of pressing needles separately connected to the first mounting component. Each of the plurality of pressing needles includes a contact portion, and a plurality of contact portions are arranged in a first direction and arranged in at least two rows in a direction perpendicular to the first direction. For two adjacent rows of contact portions, at least one of the contact portions in a first row extends between adjacent contact portions in a second row. In a case that at least one of the plurality of contact portions is in contact with the grid line, the first direction is the same as an extension direction of the grid line. The plurality of pressing needles of the conductive assembly are arranged in a plurality of rows, so that a contact area of the pressing needle and a sheet-like material in a direction perpendicular to the extension direction of the grid line is increased, so that the pressing needle better covers the grid line. Further more, part of at least one contact portion in the first row extends between the adjacent contact portions in the second row. Therefore, even if mounting accuracy of the pressing needle is not high or the pressing needle deviates slightly from the grid line during a pressing process, some of the pressing needles in the conductive assembly can still be ensured to contact the grid line, so that a probability that the pressing needle fails to contact the grid line is reduced, and a probability that the pressing needle fails to conduct electricity is further reduced.

Specific structures of the conductive assembly are described below with reference to the embodiments.

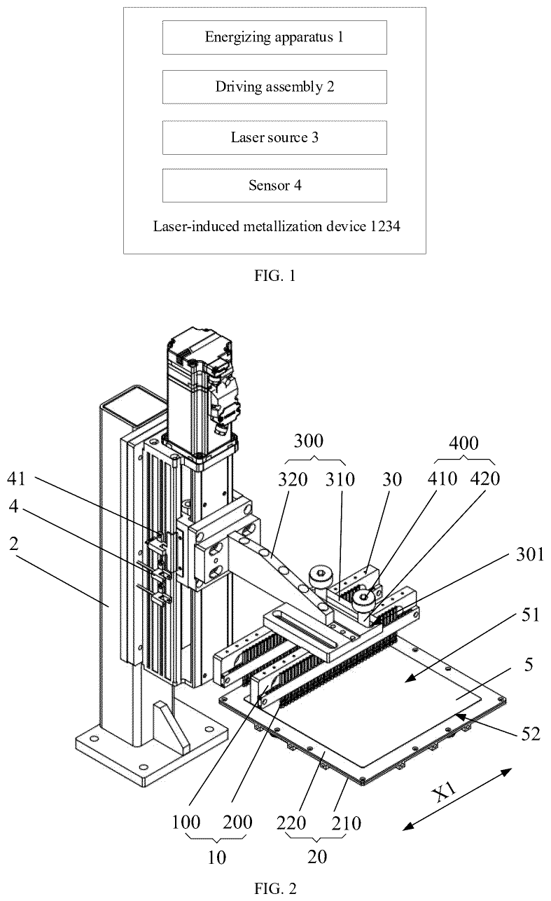

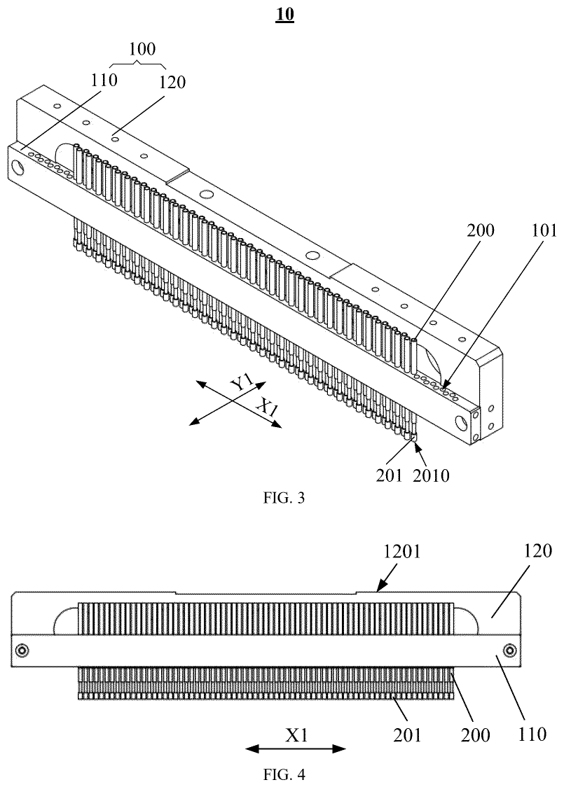

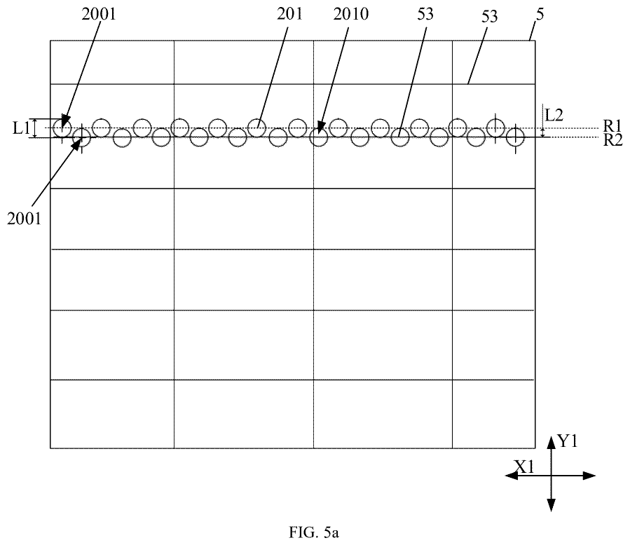

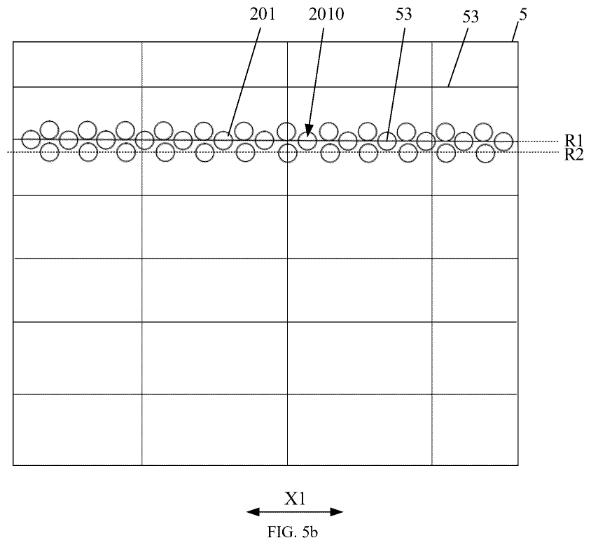

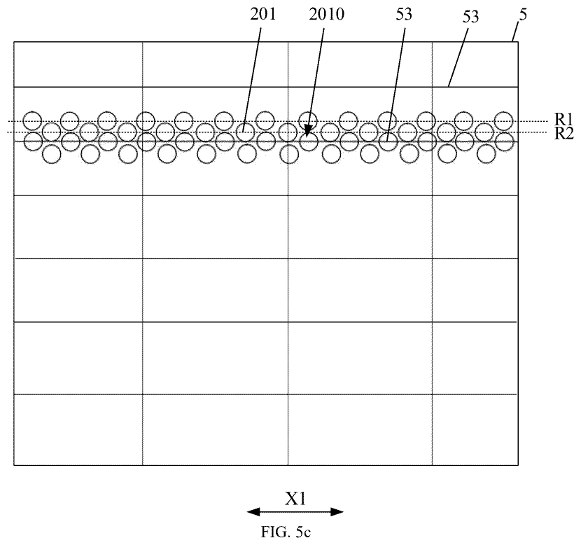

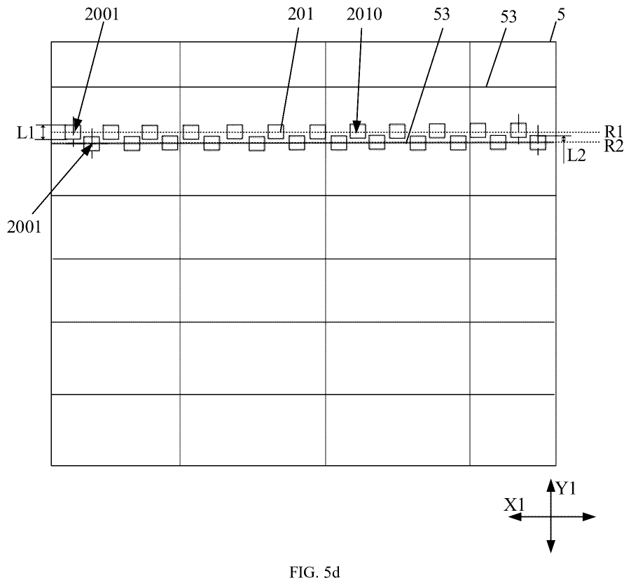

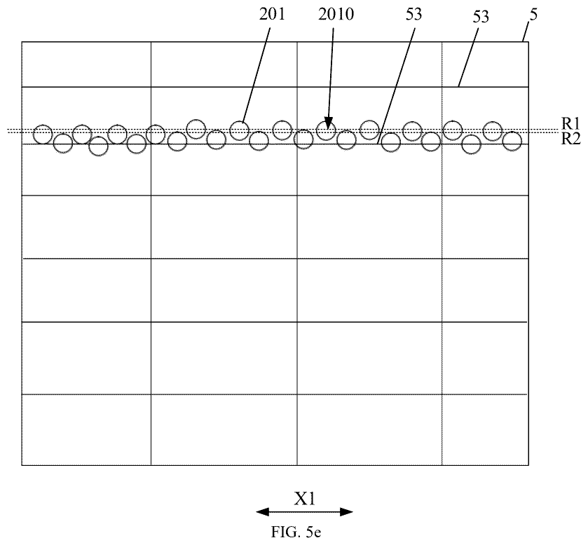

FIG. 1 is a schematic structural diagram of a laser-induced metallization device according to an embodiment of the present disclosure. FIG. 2 is a schematic structural diagram of an energizing apparatus and a driving assembly according to an embodiment of the present disclosure. FIG. 3 is a schematic structural diagram of a conductive assembly according to an embodiment of the present disclosure. FIG. 4 is a front view of a conductive assembly according to an embodiment of the present disclosure. FIG. 5a is a schematic structural diagram of a contact portion of a pressing needle and a grid line according to an embodiment of the present disclosure. FIG. 5b is a schematic structural diagram of a contact portion of a pressing needle and a grid line according to another embodiment of the present disclosure. FIG. 5c is a schematic structural diagram of a contact portion of a pressing needle and a grid line according to another embodiment of the present disclosure. FIG. 5d is a schematic structural diagram of a contact portion of a pressing needle and a grid line according to another embodiment of the present disclosure. FIG. 5e is a schematic structural diagram of a contact portion of a pressing needle and a grid line according to another embodiment of the present disclosure. As shown in FIG. 1 to FIG. 5e, a conductive assembly 10 is applied to a laser-induced metallization device 1234 for processing a sheet-like material 5. One of the conductive assembly 10 and the sheet-like material 5 can move towards or away from the other, and the conductive assembly 10 is capable of electrically connecting to a grit line 53 of a first surface 51 of the sheet-like material.

Exemplarily, the laser-induced metallization device 1234 include a driving assembly 2. The driving assembly 2 is connected to the conductive assembly 10 to drive the conductive assembly 10, so that the conductive assembly 10 is electrically connected to the grit line 53 of the first surface 51 of the sheet-like material. Exemplarily, the sheet-like material 5 is placed on a carrying platform, and the driving assembly 2 is connected to the carrying platform to drive the carrying platform, so that the conductive assembly 10 is electrically connected to the grit line 53 of the first surface 51 of the sheet-like material.

The conductive assembly 10 includes a first mounting component 100 and a plurality of pressing needles 200. The plurality of pressing needles 200 are separately connected to the first mounting component 100. The pressing needle 200 includes a contact portion 201. The plurality of contact portions 201 are arranged in a first direction X1, and are arranged in at least two rows in a direction perpendicular to the first direction X1. For two adjacent rows of contact portions 201, at least one of the contact portions 201 in a first row R1 extends between adjacent contact portions 201 in a second row R2. In a case that at least one contact portion 201 is in contact with the grid line 53, the first direction X1 is the same as an extension direction of the grid line 53.

Exemplarily, the first mounting component 100 is a special-shaped structure, or include at least two plate-shaped structures. Exemplarily, a shape of the first mounting component 100 is an L shape, a T shape, or other polygons or irregular shapes. The shape of the first mounting component 100 is not specifically limited in the present disclosure.

Exemplarily, a shape of the pressing needle 200 is a long-strip-shaped needle-shaped structure. A cross-sectional shape of the pressing needle 200 is a rectangle, a circle, or another polygon or irregular shape. The shape of the pressing needle 200 is not specifically limited in the present disclosure.

In some embodiments, a cross-sectional shape of the contact portion 201 is a circle, a rectangle, or other polygons or irregular shapes. The cross-sectional shape of the contact portion 201 is not specifically limited in the present disclosure.

In some embodiments, the sheet-like material 5 is a product such as a silicon wafer, a cell panel, and a glass substrate, etc.

As shown in FIG. 5a to FIG. 5c and FIG. 5e, cases that two rows of pressing needles 200, three rows of pressing needles 200, four rows of pressing needles 200, and a plurality of rows of pressing needles 200 arranged in a disordered manner are respectively shown.

Exemplarily, in the case that only one row of pressing needles 200 is provided (that is, only one row of contact portions 201 is provided), since one row of pressing needles 200 is arranged in the first direction X1, if one row of pressing needles 200 deviates, anyone of the contact portions 201 of one row of pressing needles 200 fails to contact the grit lines 53, resulting in the pressing needle 200 failing to conduct electricity. If two rows of pressing needles 200, three rows of pressing needles 200, four rows of pressing needles 200 or more rows of pressing needles 200 are provided, the contact portions 201 of the plurality of rows of pressing needles 200 increase a contact area between the pressing needles 200 and the sheet-liked material 5 in an extension direction perpendicular to the grit line 53, so that the pressing needles 200 can better cover the grit line 53. Therefore, even if mounting accuracy of the pressing needle 200 is not high, or the pressing needle 200 deviates slightly from the grid line 53 during a pressing process, anyone of the contact portions 201 of one row of pressing needles 200 fails to contact the grit lines 53, the pressing needle 200 in the other row may contact the grit line 53, so that the pressing needle 200 is prevented from failing to conduct electricity.

According to the embodiment of the present disclosure, the conductive assembly 10 includes: a first mounting component 100 and a plurality of pressing needles 200. The plurality of pressing needles 200 are separately connected to the first mounting component 100. The pressing needle 200 includes a contact portion 201. The plurality of contact portions 201 are arranged in a first direction X1, and are arranged in at least two rows in a direction perpendicular to the first direction X1. For two adjacent rows of contact portions 201, at least one of the contact portions 201 in a first row R1 extends between adjacent contact portions 201 in a second row R2. At least one contact portion 201 is driven by the driving assembly 2 to contact or separate from the grit line 53, and in a case that at least one contact portion 201 is in contact with the grit line 53, the first direction X1 is the same as an extension direction of the grit line 53. The plurality of pressing needles 200 of the conductive assembly 10 are arranged in a plurality of rows, so that a contact area between the pressing needles 200 and the sheet-liked material 5 in an extension direction perpendicular to the grit line 53 is increased, so that the pressing needle 200 can better cover the grit line 53, and part of at least one contact portion 201 in the first row R1 extends between adjacent contact portions 201 in the second row R2. So that even if mounting accuracy of the pressing needle 200 is not high, or the pressing needle 200 deviates slightly from the grit line 53 in a pressing process, some of the pressing needles 200 in the conductive assembly 10 can still be ensured to be in contact with the grid line 53, so that a probability that the pressing needle 200 fails to contact the grid line 53 is reduced, and a probability that the pressing needle 200 fails to conduct electricity is further reduced.

In some embodiments, as shown in FIG. 3, FIG. 5a and FIG. 5d, a distance between a geometric center 2001 of at least one contact portion in the first row R1 and a geometric center 2001 of at least one contact portion in the second row R2 in a second direction Y1 is less than or equal to the first distance L1. The second direction Y1 is perpendicular to the first direction X1 and perpendicular to an extension direction of the pressing needle 200. The first distance L1 is a size of the contact portion 201 in the second direction Y1.

In other words, on an orthographic projection surface of the pressing needle 200 on the sheet-like material 5, the distance between the geometric center 2001 of at least one contact portion in the first row R1 and the geometric center 2001 of at least one contact portion in the second row R2 in the second direction Y1 is less than or equal to the first distance L1.

The second direction Y1 is perpendicular to the first direction X1. The first distance L1 is a size of the contact portion 201 in the second direction Y1 on the orthographic projection surface.

In other words, in a case that the contact portion 201 is in contact with the first surface 51 of the sheet-like material 5, on the first surface 51 of the sheet-like material, the distance between the geometric center 2001 of at least one contact portion in the first row R1 and the geometric center 2001 of at least one contact portion in the second row R2 in the second direction Y1 is less than or equal to the first distance L1. The second direction Y1 is perpendicular to the first direction X1. The first distance L1 is a size of the contact portion 201 in the second direction Y1 on the first surface 51 of the sheet-like material.

If a distance between two rows of the contact portions 201 is too large, it may result in a gap between at least one contact portion 201 in the first row R1 and at least one contact portion 201 in the second row R2 in a direction perpendicular to the first direction X1. Once the pressing needles 200 deviate slightly from the grid line 53 during the pressing process, the grid line 53 falls within a range of the gap, and the pressing needles 200 still fail to contact the grid line 53, resulting in the pressing needles 200 failing to conduct electricity. Therefore, according to the present disclosure, a vertical distance between the geometric center 2001 of at least one contact portion in the first row R1 and the geometric center 2001 of at least one contact portion in the second row R2 is provided to be less than or equal to the first distance L1, the distance between the two rows of contact portions 201 may be prevented from being too large, thereby reducing a probability of conduction failure.

In some embodiments, as shown in FIG. 5a and FIG. 5d, a distance between the geometric center 2001 of at least one contact portion in the first row R1 and the geometric center 2001 of at least one contact portion in the second row R2 in the second direction Y1 is greater than or equal to a second distance L2. The second distance L2 is half of the size of the contact portion 201 in the second direction Y1.

If a distance between the two rows of contact portions 201 is too short, it may result in that a contact area between added pressing needle 200 and the sheet-like material 5 in the direction perpendicular to the extension direction of the grit line 53 is limited, resulting in a limited reduction in the probability that the pressing needle 200 fails to contact the grid line 53, and consequently, a limited reduction in the probability that the pressing needle 200 fails to conduct electricity. Therefore, according to the present disclosure, the distance between the geometric center 2001 of at least one contact portion in the first row R1 and the geometric center 2001 of at least one contact portion in the second row R2 in the second direction Y1 is provided to be greater than or equal to a second distance L2, so that the distance between the two rows of contact portions 201 may be prevented from being too short, so as to increase a contact area between the pressing needle 200 and the sheet-like material 5 in the direction perpendicular to the extension direction of the grit line 53, thereby reducing the probability that the pressing needle 200 fails to contact the grit line 53, and further reducing the probability of conduction failure.

Therefore, the distance between the two rows of contact portions 201 is preferred to be increased for increasing the contact area between the pressing needle 200 and the sheet-like material 5 in the direction perpendicular to the extension direction of the grit line 53. So that the probability that the pressing needle 200 fails to contact the grit line 53 is further reduced, and the probability that the pressing needle 200 fails to conduct electricity is further reduced.

In some embodiments, the contact portion 201 includes a contact surface 2010 for contacting the sheet-like material 5. A shape of the contact surface 2010 includes a central symmetry shape.

Exemplarily, the shape of the contact surface 2010 is circular, rectangular, or other central symmetry shapes. The shape of the contact surface 2010 is not specifically limited in the present disclosure.

Exemplarily, the shape of the contact surface 2010 is circular or rectangular. As shown in FIG. 5a, when the shape of the contact surface 2010 is circular, the first distance L1 is a length of a diameter of the contact surface 2010, and the second distance L2 is a length of a radius of the contact surface 2010. As shown in FIG. 5d, when the shape of the contact surface 2010 is rectangular, the first distance L1 is a size of the contact surface 2010 in a direction perpendicular to the first direction X1 and the extension direction of the pressing needle 200, and the second distance L2 is half of the size of the contact surface 2010 in the direction perpendicular to the first direction X1 and the extension direction of the pressing needle 200.

When the shape of the contact surface 2010 is circular or rectangular, and the distance between the two rows of contact portions 201 is less than or equal to the first distance L1 and greater than or equal to the second distance L2, not only can the contact area between the pressing needle 200 and the sheet-like material 5 in the direction perpendicular to the extension direction of the grit line 53 be increased as much as possible, but also may prevent the two rows of contact portions 201 from having a gap in the direction perpendicular to the first direction X1. So that the probability that the pressing needle 200 fails to contact the grit line 53 is further reduced, and the probability that the pressing needle 200 fails to conduct electricity is further reduced.

In some embodiments, a plurality of contact portions 201 in the first row R1 are linearly arranged in the first direction X1, and a plurality of contact portions 201 in the second row R2 are linearly arranged in the first direction X1, so that the plurality of contact portions 201 uniformly contact a plurality of points of the grit line 53 in the first direction X1, and a current of the sheet-like material 5 is more uniform.

In other words, the plurality of contact portions 201 are arranged in the first direction X1, and distances between the plurality of contact portions 201 are equal, so that the plurality of contact portions 201 uniformly contact the plurality of points of the grit line 53 in the first direction X1, so that the plurality of contact portions 201 apply a voltage to the plurality of uniform points, and lengths of the grit line 53 connected to adjacent points are the same. Therefore, resistances of the grit line 53 connected to adjacent points are equal, and currents on the grit line 53 connected to adjacent points are the same, so that the current of the sheet-like material 5 is more uniform.

In some embodiments, as shown in FIG. 5a and FIG. 5d, the plurality of contact portions 201 are arranged in two rows in the first direction X1. The contact portion 201 includes a contact surface 2010 for contacting the sheet-like material 5. A shape of the contact surface 2010 includes a circle shape. On a plane perpendicular to the first direction X1, a vertical distance between the geometric center 2001 of the contact portion in the first row RI and the geometric center 2001 of the contact portion in the second row R2 is less than or equal to the first distance L1 and greater than or equal to the second distance L2, so that an optimal distance is maintained between the two rows of contact portions 201.

In some embodiments, as shown in FIG. 3, the first mounting component 100 includes a plurality of mounting holes 101. The pressing needle 200 is embedded in the mounting hole 101. In other words, the pressing needle 200 and the mounting hole 101 are in an interference connection.

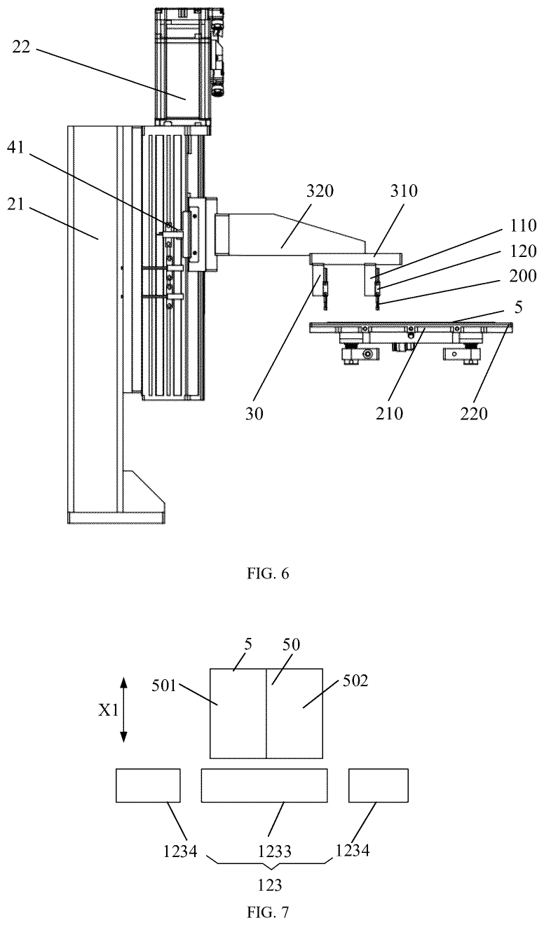

In some embodiments, as shown in FIG. 2 and FIG. 6, the conductive assembly 10 further includes: a second mounting component 300 and a locking member 400. The second mounting component 300 includes a long groove 301. An extension direction of the long groove 301 is perpendicular to the first direction X1 and is perpendicular to an extension direction of the pressing needle 200. The locking member 400 includes a limiting portion 410 and a screw-connecting portion 420. The limiting portion 410 is located on one side of the second mounting component 300. The screw-connecting portion 420 passes through the long groove 301 from one side of the second mounting component 300 and is screwed to the first mounting component 100 located on the other side of the second mounting component 300. The long groove 301 is used to adjust a contact position of the pressing needle 200 on the sheet-like material 5, so that contact surfaces 2010 of the plurality of pressing needles 200 are in contact with the grit line 53.

Exemplarily, the second mounting component 300 includes at least two plate-shaped structures, and the plate-shaped structures are fixedly connected. Exemplarily, a shape of the second mounting component 300 is an L shape, a T shape, or other polygons or irregular shapes. The shape of the first mounting component 100 is not specifically limited in the present disclosure.

Exemplarily, as shown in FIG. 2 and FIG. 6, the second mounting component 300 is located on an upper side of the first mounting component 100 and the pressing needle 200. The limiting portion 410 is located on an upper side of the second mounting component 300. The screw-connecting portion 420 passes through the long groove 301 from the upper side of the second mounting component 300 and is screwed to the first mounting component 100 located on a lower side of the second mounting component 300.

In some embodiments, as shown in FIG. 2, FIG. 4 and FIG. 6, the pressing needle 200 is vertically disposed. The first mounting component 100 includes: a first mounting plate 110 and a second mounting plate 120. The first mounting plate 110 is connected to the plurality of pressing needles 200. The second mounting plate 120 is connected to the first mounting plate 110 and is also connected to the second mounting component 300, and a vertical height of an upper surface 1201 of the second mounting plate is greater than a vertical height of the first mounting plate 110. The second mounting component 300 includes: a third mounting plate 310 and a fourth mounting plate 320. The third mounting plate 310 includes the long groove 301. The fourth mounting plate 320 is connected to the third mounting plate 310. The limiting portion 410 is located on one side of the third mounting plate 310. The screw-connecting portion 420 passes through the long groove 301 from one side of the third mounting plate 310 and is screwed to the second mounting plate 120 located on the other side of the third mounting plate 310. The first mounting plate 110 and the second mounting plate 120 have a simple and reliable structure.

Exemplarily, as shown in FIG. 3, the first mounting plate 110 includes a plurality of mounting holes 101. The plurality of pressing needles 200 vertically penetrate through the plurality of mounting holes 101 respectively and are embedded in the plurality of mounting holes 101. The contact portion 201 is located at a lower end of the pressing needle 200, and a contact surface 2010 is a lower side surface of the contact portion 201.

Exemplarily, the first mounting plate 110 is vertically disposed. The second mounting plate 120 is vertically disposed. As shown in FIG. 2 and FIG. 6, the third mounting plate 310 is located on an upper side of the first mounting plate 110, the second mounting plate 120, and the pressing needle 200. The third mounting plate 310 is horizontally disposed. The limiting portion 410 is located on an upper side of the third mounting plate 310. The screw-connecting portion 420 passes through the long groove 301 from the upper side of the third mounting plate 310 and is screwed to the second mounting plate 120 located on a lower side of the third mounting plate 310.

The present disclosure further provides an energizing apparatus. As shown in FIG. 1 and FIG. 2, the energizing apparatus 1 is applied to a laser-induced metallization device 1234 for processing a sheet-like material 5. The energizing apparatus includes: the conductive assembly 10 mentioned in the foregoing embodiment and a conductive support assembly 20. The conductive assembly 10 and the sheet-like material 5 are capable of moving towards or away from each other, and the conductive assembly 10 is electrically connected to a grit line 53 of a first surface 51 of the sheet-like material 5. The conductive support assembly 20 is configured to carry the sheet-like material 5 and be electrically connected to a second surface 52 of the sheet-like material 5.

Exemplarily, the conductive support assembly 20 is electrically connected to a power supply through a wire, and the conductive support assembly 20 applies a voltage to the second surface 52 of the sheet-like material 5.

Exemplarily, the conductive support assembly 20 may alternatively be electrically connected to other structures with a conductive function, other structures with the conductive function are electrically connected to the power supply, and other structures with the conductive function and the conductive support assembly 20 are configured for applying a voltage to the second surface 52 of the sheet-like material. Other structures with the conductive function include a pressing needle, the pressing needle is used for an electrical connection with the conductive support assembly 20. Other structures with the conductive function may alternatively be other types of structures that do not include a pressing needle.

In some embodiments, the energizing apparatus 1 further includes a pressing needle conductive structure 30. The pressing needle conductive structure 30 is capable of being electrically connected to the conductive support assembly 20.

The pressing needle conductive structure 30 is used to apply a voltage to the second surface 52 of the sheet-like material, instead of using the conductive support assembly 20 to apply the voltage to the second surface 52 of the sheet-like material, a wire connected to the conductive support assembly 20 is avoided from being wound around the conductive support assembly 20 that needs to move, so that the wire is avoided from affecting a movement of the conductive support assembly 20.

Exemplarily, as shown in FIG. 2 and FIG. 6, a structure of the pressing needle conductive structure 30 is the same as a structure of the conductive assembly 10, and the pressing needle conductive structure 30 and the conductive assembly 10 are spaced parallel in a direction perpendicular to the first direction X1.

In some embodiments, the pressing needle conductive structure 30 may further be other structures including a pressing needle. Exemplarily, a structure of the pressing needle of the pressing needle conductive structure 30 is the same as a structure of the pressing needle 200, or is pressing needle with other types. The structure of the pressing needle of the pressing needle conductive structure 30 is not specifically limited in the present disclosure.

In some embodiments, as shown in FIG. 2, the conductive support assembly 20 includes a carrying platform 210 and a conductive plate 220. The conductive plate 220 is disposed on the carrying platform 210, configured to carry the sheet-like material 5, and electrically connected to the second surface 52 of the sheet-like material. The conductive plate 220 is used for conductivity, and a structure of conductive plate 220 is simple and reliable.

Exemplarily, as shown in FIG. 6, the carrying platform 210 is horizontally disposed. The conductive plate 220 is horizontally disposed on an upper side of the carrying platform 210. The sheet-like material 5 is horizontally disposed on an upper side of the conductive plate 220.

Exemplarily, the conductive plate 220 is produced by metal, such as copper, iron, or other metal materials with a conductive function. The material of the conductive plate 220 is not specifically limited in the present disclosure.

Since the energizing apparatus 1 includes the conductive assembly 10, the energizing apparatus 1 has all technical features and technical effects of the conductive assembly 10, and details are not described herein again.

The present disclosure further provides a laser-induced metallization device. As shown in FIG. 1 and FIG. 2, the laser-induced metallization device 1234 includes: the energizing apparatus 1 mentioned in the foregoing embodiments, a driving assembly 2, and a laser source 3. The driving assembly 2 is configured to provide a driving force. The energizing apparatus 1 is connected to the driving assembly 2. The driving assembly 2 is configured to drive the energizing apparatus 1, so that the energizing apparatus 1 energizes a sheet-like material 5. The laser source 3 is disposed above the conductive support assembly 20 and is configured to perform laser-induced metallization on the sheet-like material 5 when the sheet-like material 5 is energized.

Exemplarily, the driving assembly 2 is a linear module, a mechanical arm, or other assemblies with a lifting and lowering function. The driving assembly 2 is not specifically limited in the present disclosure.

Exemplarily, the pressing needle conductive structure 30 is connected to the driving assembly 2, and is capable of electrical connecting to the conductive support assembly 20 under driving of the driving assembly 2. A connection manner between the pressing needle conductive structure 30 and the driving assembly 2 is the same as a connection manner between the conductive assembly 10 and the driving assembly 2, and details are not described herein again. A distance between the pressing needle conductive structure 30 and the conductive assembly 10 is adjusted through the long groove 301.

In some embodiments, the laser source 3 is configured to scan the first surface 51 of the sheet-like material 5 in a case that the sheet-like material 5 is energized, so as to perform laser-induced metallization on the sheet-like material 5.

In some embodiments, the driving assembly 2 includes: a support member 21 and a lifting and lowering component 22. The lifting and lowering component 22 is connected to the support member 21 and is connected to the energizing apparatus 1, and is configured to drive the energizing apparatus 1 to rise and fall.

Exemplarily, as shown in FIG. 6, the support member 21 is vertically disposed. The lifting and lowering component 22 is connected to the support member 21, and moves back and forth in a vertical direction. The lifting and lowering component 22 is connected to the fourth mounting plate 320.

Exemplarily, the lifting and lowering component 22 is a linear module, a mechanical arm, or other components with a lifting function. The lifting and lowering component is not specifically limited in the present disclosure.

In some embodiments, the laser-induced metallization device 1234 further includes at least one sensor 4. The sensor 4 is disposed on the support member 21 or the lifting and lowering component 22, and is configured to detect a vertical position of the energizing apparatus 1.

Exemplarily, the sensor 4 is a micro switch, a slot-type photoelectric sensor, or is a sensor in other types. The sensor 4 is not specifically limited in the present disclosure.

Exemplarily, as shown in FIG. 2, FIG. 6 and FIG. 9, the sensor 4 is a slot-type photoelectric sensor 40. The slot-type photoelectric sensor 40 includes an induction slot 45. The number of the slot-type photoelectric sensors 40 is at least three, and at least three of the slot-type photoelectric sensors 40 are disposed on the support member 21 at intervals in an extension direction of the support member 21. The driving assembly 2 further includes a light blocking sheet 41. The light blocking sheet 41 is connected to the lifting and lowering component 22, rises and falls with the lifting and lowering component 22, and is capable of inserting into the induction slot 45. The light blocking sheet 41 is configured to detect a vertical position of the energizing apparatus 1. One sensor 4 is configured to define an origin position of the lifting and lowering component 22, that is, a middle position. The other two sensors 4 are configured to define end positions of a displacement of the lifting and lowering component 22. Specifically, the at least three sensors 4 include the first slot-type photoelectric sensor 42, the second slot-type photoelectric sensor 43, and the third slot-type photoelectric sensor 44. The first slot-type photoelectric sensor 42 is configured to detect the origin position of the lifting and lowering component 22. The second slot-type photoelectric sensor 43 is configured to detect a rising end point position of the lifting and lowering component 22. The third slot-type photoelectric sensor 44 is configured to detect a falling end point position of the lifting and lowering component 22. The first slot-type photoelectric sensor 42 is located between the second slot-type photoelectric sensor 43 and the third slot-type photoelectric sensor 44. By means of the sensor 4, the position of the conductive assembly 10 can be accurately adjusted, so that the pressing needle 200 can be ensured to contact the grit line 53, and the pressing needle 200 is prevented from excessively pressing the grit line 53 to cause fragmentation of the sheet-like material 5.

Since the laser-induced metallization device 1234 includes the energizing apparatus 1, the laser-induced metallization device 1234 has all technical features and technical effects of the energizing apparatus 1, and details are not described herein again.

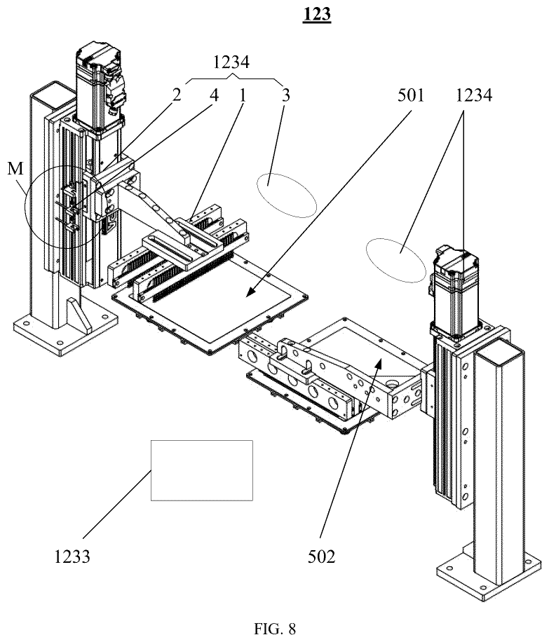

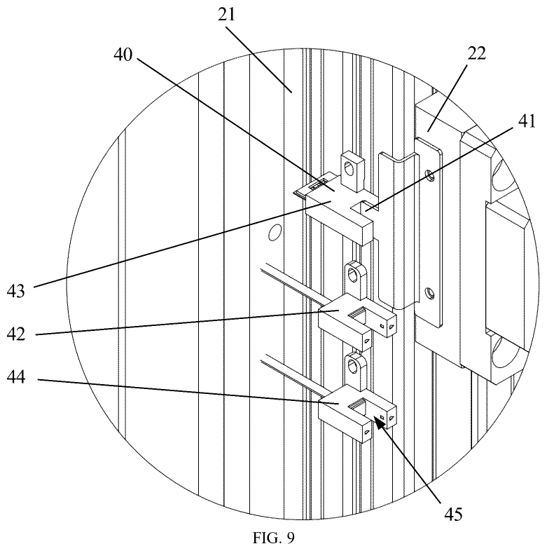

The present disclosure further provides a laser-induced metallization production line. FIG. 7 is a schematic structural diagram of a laser-induced metallization production line according to an embodiment of the present disclosure. FIG. 8 is a schematic structural diagram of a laser-induced metallization production line according to another embodiment of the present disclosure. As shown in FIG. 7 and FIG. 8, the laser-induced metallization production line 123 includes: a plurality of laser-induced metallization devices 1234 mentioned in the above embodiments and a transportation device 1233. The plurality of laser-induced metallization devices 1234 respectively perform laser-induced metallization on a plurality of areas 50 to be processed of the sheet-like material 5. The transportation device 1233 is configured to transport the sheet-like material 5 from one laser-induced metallization device 1234 to another laser-induced metallization device 1234.

Exemplarily, the laser-induced metallization production line 123 includes two laser-induced metallization devices 1234 mentioned in the above embodiments and the transportation device 1233. The sheet-like material 5 includes two to-be-processed areas 50, that is, a first to-be-processed area 501 and a second to-be-processed area 502. The two laser-induced metallization devices 1234 respectively perform laser-induced metallization on the first to-be-processed area 501 and the second to-be-processed area 502.

Exemplarily, the transportation device 1233 includes a turntable. The sheet-like material 5 is transported from one laser-induced metallization device 1234 to another laser-induced metallization device 1234 through a rotating of the turntable. Exemplarily, the transportation device 1233 may further include a mechanical arm. The sheet-like material 5 is transported from one laser-induced metallization device 1234 to another laser-induced metallization device 1234 through a movement of the mechanical arm. Exemplarily, the transportation device 1233 may further be a device including a conveyor belt or other structures having a motion function. A structure of the transportation device 1233 is not specifically limited in the present disclosure.

In some embodiments, a working area of the laser-induced metallization device 1234 covers the to-be-processed area 50, so that the plurality of laser-induced metallization devices 1234 perform laser-induced metallization on an entire first surface 51 of the sheet-like material.

Exemplarily, a working area of one laser-induced metallization device 1234 covers the first to-be-processed area 501 and part of the second to-be-processed area 502, and a working area of the other laser-induced metallization device 1234 covers part of the first to-be-processed area 501 and the second to-be-processed area 502, so that the entire first surface 51 of the sheet-like material is subjected to laser-induced metallization through the two laser-induced metallization devices 1234.

Since the laser-induced metallization production line 123 includes the laser-induced metallization device 1234, the laser-induced metallization production line 123 has all technical features and technical effects of the laser-induced metallization device 1234, and details are not described herein again.

In the embodiments of the present disclosure, if a connection form is not explicitly defined, the connection form is a detachable connection form such as a bolt nut, a screw, a buckle, and a magnetic attraction. If there is no special requirement in a form of non-detachable cooperation in some connections, a non-detachable connection is performed in a manner of welding, bonding, and the like.

“One embodiment”, “an embodiment” or the like mentioned in the specification means that the embodiment described may include a particular feature, structure, or characteristic, but not necessarily every embodiment includes the particular feature, structure, or characteristic. Moreover, such phrases are not necessarily referring to the same embodiment. In addition, when a particular feature, structure, or characteristic is described in connection with an embodiment, it is within a knowledge range of a person skilled in the art to implement such features, structures, or features in conjunction with other embodiments that are explicitly or not explicitly described.

It should be understood that the terms “on”, “above”, and “over” in the present disclosure should be interpreted in the widest possible way, so that “on” not only means “directly on something”, but also includes “above something” with intermediate features or layers between them, and “upper” or “above” not only includes the meaning of “over something” or “above something”, but can also include the meaning of “over something” or “above something” without intermediate features or layers (that is, directly on something).

In addition, for ease of description, spatial relative terms, for example, “lower”, “below”, “under”, “over”, “above”, and the like may be used in the specification to describe the relationship between a component or feature and other components or features as shown in the figure. The term spatial relative refers to the different orientations of components in use or operation, other than those shown in the accompanying drawings. The device may have other orientations (rotated 90° or in other orientations), and the spatial relative descriptors used in the specification may also be explained accordingly.

It should be noted that in this specification, the terms “include”, “comprise”, or any other variant thereof are intended to cover non-exclusive inclusion, so that a process, method, article, or device that includes a series of elements includes not only those elements, but also includes other elements that are not explicitly listed, or further includes elements inherent to the process, method, article, or device. In an absence of more restrictions, the statement “includes one . . . ” does not exclude the existence of other identical elements in the process, method, item, or device that includes the said elements.

The above are only preferred embodiments of the present disclosure and are not intended to limit the present disclosure. Any modification, equivalent replacement, and the like made within the spirit and principle of the present disclosure should be included in the protection scope of the present disclosure.

What is claimed is:

1. A conductive assembly, applied to a laser-induced metallization device for processing a sheet-like material, wherein the conductive assembly and the sheet-like material are capable of moving towards or away from each other, and the conductive assembly is capable of electrically connecting to a grid line of a first surface of the sheet-like material, wherein
the conductive assembly comprises:
a first mounting component; and
a plurality of pressing needles, separately connected to the first mounting component, wherein each of the plurality of pressing needles comprises a contact portion, a plurality of contact portions are arranged in a first direction and arranged in at least two rows in a direction perpendicular to the first direction, and for two adjacent rows of contact portions, at least one of the contact portions in a first row extends between adjacent contact portions in a second row, wherein
in a case that at least one of the plurality of contact portions is in contact with the grid line, the first direction is the same as an extension direction of the grid line.

2. The conductive assembly according to claim 1, wherein a distance between a geometric center of at least one of the contact portions in the first row and a geometric center of at least one of the contact portions in the second row in a second direction is less than or equal to a first distance,
the second direction is perpendicular to the first direction and perpendicular to an extension direction of the plurality of pressing needles, and the first distance is a size of one of the plurality of contact portions in the second direction.

3. The conductive assembly according to claim 2, wherein a distance between the geometric center of at least one of the contact portions in the first row and the geometric center of at least one of the contact portions in the second row in the second direction is greater than or equal to a second distance,
the second distance is half of the size of one of the plurality of contact portions in the second direction.

4. The conductive assembly according to claim 3, wherein the contact portion comprises a contact surface for contacting the sheet-like material, and a shape of the contact surface comprises a central symmetry shape.

5. The conductive assembly according to claim 3, wherein a plurality of contact portions in the first row are linearly arranged in the first direction, and a plurality of contact portions in the second row are linearly arranged in the first direction.

6. The conductive assembly according to claim 5, wherein
the plurality of contact portions are arranged in two rows in the first direction;
the contact portion comprises a contact surface for contacting the sheet-like material, and a shape of the contact surface comprises a circle shape; and
on a plane perpendicular to the first direction, a vertical distance between the geometric center of the contact portion in the first row and the geometric center of the contact portion in the second row is less than or equal to the first distance and greater than or equal to the second distance.

7. The conductive assembly according to claim 1, wherein the first mounting component comprises a plurality of mounting holes,
the plurality of pressing needles are respectively embedded in the plurality of mounting holes.

8. The conductive assembly according to claim 1, further comprising:
a second mounting component, wherein the second mounting component comprises a long groove, and an extension direction of the long groove is perpendicular to the first direction and is perpendicular to an extension direction of the plurality of pressing needles; and
a locking member, comprising a limiting portion and a screw-connecting portion, wherein the limiting portion is located on one side of the second mounting component, and the screw-connecting portion passes through the long groove from one side of the second mounting component and is screwed to the first mounting component located on the other side of the second mounting component.

9. The conductive assembly according to claim 8, wherein the plurality of pressing needles are vertically disposed,
the first mounting component comprises:
a first mounting plate, connected to the plurality of pressing needles; and
a second mounting plate, connected to the first mounting plate and connected to the second mounting component, wherein a vertical height of an upper surface of the second mounting plate is greater than a vertical height of the first mounting plate; wherein
the second mounting component comprises:
a third mounting plate, comprising the long groove; and
a fourth mounting plate, connected to the third mounting plate, wherein
the limiting portion is located on one side of the third mounting plate, and the screw-connecting portion passes through the long groove from one side of the third mounting plate and is screwed to the second mounting plate located on the other side of the third mounting plate.

10. An energizing apparatus, applied to a laser-induced metallization device for processing a sheet-like material, wherein the energizing apparatus comprises:
a conductive assembly, wherein the conductive assembly is capable of electrical connecting to a grid line of a first surface of the sheet-like material; and
a conductive support assembly, configured to carry the sheet-like material and be electrically connected to a second surface of the sheet-like material, wherein
the conductive assembly comprises:
a first mounting component; and
a plurality of pressing needles, separately connected to the first mounting component, wherein each of the plurality of pressing needles comprises a contact portion, a plurality of contact portions are arranged in a first direction and arranged in at least two rows in a direction perpendicular to the first direction, and for two adjacent rows of contact portions, at least one of the contact portions in a first row extends between adjacent contact portions in a second row, wherein
in a case that at least one of the plurality of contact portions is in contact with the grid line, the first direction is the same as an extension direction of the grid line.

11. The energizing apparatus according to claim 10, further comprising:
a pressing needle conductive structure, capable of being electrically connected to the conductive support assembly.

12. The energizing apparatus according to claim 10, wherein the conductive support assembly comprises:
a carrying platform;
a conductive plate, disposed on the carrying platform, configured to carry the sheet-like material, and electrically connected to the second surface of the sheet-like material.

13. A laser-induced metallization device, comprising:
a driving assembly, configured to provide a driving force;
an energizing apparatus, connected to the driving assembly, wherein the driving assembly is configured to drive the energizing apparatus, so that the energizing apparatus energizes the sheet-like material;
a laser source, disposed above the energizing apparatus and configured to perform laser-induced metallization on the sheet-like material when the sheet-like material is energized, wherein
the energizing apparatus comprises:
a conductive assembly, wherein the conductive assembly and the sheet-like material are capable of moving towards or away from each other, and the conductive assembly is capable of electrical connecting to a grid line of a first surface of the sheet-like material; and
a conductive support assembly, configured to carry the sheet-like material and electrically connected to a second surface of the sheet-like material, wherein
the conductive assembly comprises:
a first mounting component; and
a plurality of pressing needles, separately connected to the first mounting component, wherein each of the plurality of pressing needles comprises a contact portion, a plurality of contact portions are arranged in a first direction and arranged in at least two rows in a direction perpendicular to the first direction, and for two adjacent rows of contact portions, at least one of the contact portions in a first row extends between adjacent contact portions in a second row, wherein
in a case that at least one of the plurality of contact portions is in contact with the grid line, the first direction is the same as an extension direction of the grid line.

14. The laser-induced metallization device according to claim 13, wherein the laser source is configured to scan the first surface of the sheet-like material in a case that the sheet-like material is energized, so as to perform laser-induced metallization on the sheet-like material.

15. The laser-induced metallization device according to claim 13, wherein the driving assembly comprises:
a support member; and
a lifting and lowering component, connected to the support member and connected to the energizing apparatus, and configured to drive the energizing apparatus to rise and fall.

16. The laser-induced metallization device according to claim 15, further comprising:
at least one sensor, disposed on the support member or the lifting and lowering component and configured to detect a vertical position of the energizing apparatus.

17. The laser-induced metallization device according to claim 16, wherein each of the at least one sensor comprises:
a slot-type photoelectric sensor, wherein the slot-type photoelectric sensor comprises an induction slot, wherein
the driving assembly further comprises:
a light blocking sheet, connected to the lifting and lowering component and rising and falling with the lifting and lowering component, wherein the light blocking sheet is capable of inserting into the induction slot.

18. The laser-induced metallization device according to claim 17, wherein a number of the slot-type photoelectric sensors is at least three, and the at least three slot-type photoelectric sensors are disposed on the support member at intervals along an extension direction of the support member,
a first slot-type photoelectric sensor is configured to detect an origin position of the lifting and lowering component; a second slot-type photoelectric sensor is configured to detect a rising end point position of the lifting and lowering component; and a third slot-type photoelectric sensor is configured to detect a falling end point position of the lifting and lowering component, wherein the first slot-type photoelectric sensor is located between the second slot-type photoelectric sensor and the third slot-type photoelectric sensor.

19. A laser-induced metallization production line, comprising:
a plurality of laser-induced metallization devices according to claim 13, respectively performing laser-induced metallization on a plurality of to-be-processed areas of a sheet-like material; and
a transportation device, configured to transport the sheet-like material from one laser-induced metallization device to another laser-induced metallization device.

20. The laser-induced metallization production line according to claim 19, wherein a working area of the laser-induced metallization device covers the to-be-processed area, so that the plurality of laser-induced metallization devices perform laser-induced metallization on an entire first surface of the sheet-liked material.
